(19) United States
(12) Patent Application Publication
(10) Pub. No.: US 2018/0076340 A1
(43) Pub. Date: Mar. 15, 2018

(54) SOLAR CELL

(71) Applicant: PANASONIC INTELLECTUAL PROPERTY MANAGEMENT CO., LTD., Osaka (JP)

(72) Inventor: Toshiaki Baba, Osaka (JP)

(73) Assignee: PANASONIC INTELLECTUAL PROPERTY MANAGEMENT CO., LTD., Osaka (JP)

(21) Appl. No.: 15/817,551

(22) Filed: Nov. 20, 2017

Related U.S. Application Data
(63) Continuation of application No. PCT/JP2016/002267, filed on May 9, 2016.

(30) Foreign Application Priority Data
May 29, 2015 (JP) 2015-109839

(51) Int. Cl. H01L 31/0216; H01L 31/18; H01L 31/068; H01L 31/0288; H01L 31/0224

(52) U.S. Cl. CPC H01L 31/02167; H01L 31/1868; H01L 31/022441; H01L 31/0288; H01L 31/068

(57) ABSTRACT

According to one embodiment of the present invention, a solar cell is provided with an n-type crystalline silicon substrate, and a passivation layer formed on the light receiving surface of the substrate, said passivation layer having a carrier generating function. The n-type crystalline silicon substrate has a doped layer in the vicinity of an interface to the passivation layer, said doped layer being doped to have a conductivity type equal to that of the substrate, and being doped at a dopant concentration equal to or higher than 1×10¹⁷ cm⁻³. The average value of the dopant concentration of the doped layer is 1×10¹⁷-1×10²⁰ cm⁻³, and the thickness of the doped layer is equal to or less than 200 nm.

### TECHNICAL FIELD

The present disclosure relates to solar cells.

### BACKGROUND ART

In solar cells including a crystalline semiconductor substrate, recombination of photogenerated carriers on the light receiving surface-side (light receiving surface) of the substrate significantly influences their output power. Thus, a passivation layer is formed on the light receiving surface of the crystalline silicon substrate. For example, Patent Literature 1 discloses a solar cell including a p-side electrode and an n-side electrode formed on the rear surface side of an n-type monocrystal silicon substrate, wherein the solar cell includes an amorphous silicon layer as a passivation layer formed on the light receiving surface of the silicon substrate.

### CITATION LIST

### Patent Literature

Patent Literature 1: International Publication No. WO 2012/132615

### SUMMARY OF INVENTION

### Technical Problem

Even in the case where a passivation layer is provided, complete inhibition of recombination of photogenerated carriers on the interface between the crystalline silicon substrate and the passivation layer has not been achieved, and thus further inhibition of the recombination has been required.

### Solution to Problem

A solar cell of an aspect of the present disclosure includes a crystalline silicon substrate and a passivation layer formed on the light receiving surface of the crystalline silicon substrate, wherein the passivation layer has a carrier generating function. The crystalline silicon substrate has a doped layer in the vicinity of the interface between the crystalline silicon substrate and the passivation layer, wherein the doped layer is doped to have the same conductivity type as that of the substrate, and has a dopant concentration equal to or higher than 1×10¹⁷ cm⁻³. The average value of the dopant concentration value of the doped layer is 1×10¹⁷ cm⁻³ to 1×10²⁰ cm⁻³, and the thickness of the doped layer is equal to or less than 200 nm.

### Advantageous Effects of Invention

According to the solar cell of an aspect of the present disclosure, recombination of photogenerated carriers on the light receiving surface of the crystalline silicon substrate may be inhibited to thereby enhance its output power.

### BRIEF DESCRIPTION OF DRAWINGS

FIG. 1 is a sectional view of a solar cell, which is an example of an embodiment.

FIG. 2 is a graph showing the relation between the dopant concentration and the relative output power value of the n⁺ layer in the solar cell, which is an example of the embodiment.

FIG. 3 is a graph showing the relation between the thickness and the relative output power value of the n⁺ layer in the solar cell, which is an example of the embodiment.

FIG. 4 is a sectional view of a solar cell, which is another example of the embodiment.

### DESCRIPTION OF EMBODIMENTS

In the solar cell, which is one aspect of the present disclosure, the crystalline silicon substrate has a specific doped layer in the vicinity of the interface between the crystalline silicon substrate and the passivation layer, wherein the doped layer is doped to have the same conductivity type as that of the substrate. As described above, even in the case where the passivation layer is provided, defects leading to a recombination level occur due to various causes on the interface between the crystalline silicon substrate and the crystalline silicon substrate, and photogenerated carriers that have been generated are recombined on the interface. The present inventors have focused on the point that the passivation layer has a carrier generating function, and have found that providing the doped layer described above in the vicinity of the interface between the crystalline silicon substrate and the passivation layer of the crystalline silicon substrate enables inhibition of recombination of photogenerated carriers that have been generated in the passivation layer to thereby enhance the output power of the solar cell.

Hereinbelow, an example of the embodiment will be described in detail, with reference to the drawings.

The drawings referred to in the description of the embodiment are depicted schematically, and the dimensional ratios of components and the like depicted in the drawings may be different from the actual situation. Specific dimensional ratios and the like should be determined by taking the following description into account. The expression “approximately **” herein is intended as follows: for a specific example, an approximately whole area is intended to encompass not only a whole area but also an area regarded as substantially a whole area.

In the description of the embodiment, an n-type crystalline silicon substrate is exemplified as the crystalline silicon substrate. In the case where the n-type crystalline silicon substrate is used, an n⁺ layer doped into an n-type is employed as a doped layer. The crystalline silicon substrate may be a p-type crystalline silicon substrate. In this case, a p⁺ layer doped into a p-type is employed as the doped layer.

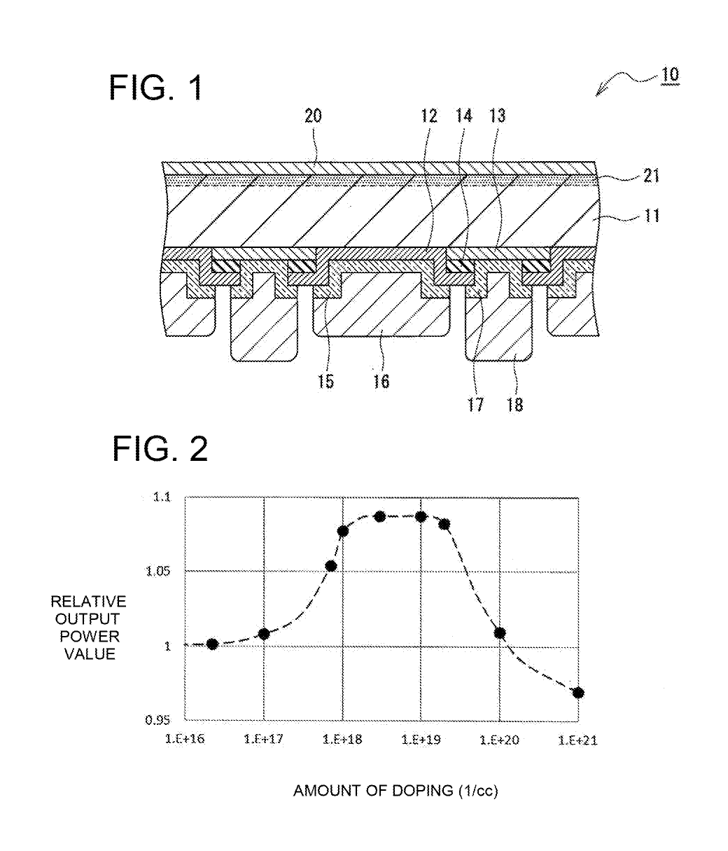

FIG. 1 is a sectional view showing a solar cell 10, which is an example of an embodiment.

As shown in FIG. 1, the solar cell 10 includes an n-type crystalline silicon substrate 11 and a passivation layer 20 formed on the light receiving surface of the substrate. The passivation layer 20 is a photovoltaic layer having a carrier generating function in addition to a passivation function by which recombination of photogenerated carriers on the light receiving surface of the n-type crystalline silicon substrate 11 is inhibited. The solar cell 10 includes a p-type semiconductor layer 12 and an n-type semiconductor layer 13 formed on the rear surface of the n-type crystalline silicon substrate 11. As described later in detail, the p-type semiconductor layer 12 and the n-type semiconductor layer 13 are partially overlapped with each other, and an insulation layer 14 is provided between the layers.

The “light receiving surface” of the n-type crystalline silicon substrate 11 (solar cell 10) means a surface which light mainly enters (more than 50% to 100%), and the “rear surface” means a surface on the opposite side to the light receiving surface. In the present embodiment, approximately the entire light entering the n-type crystalline silicon substrate 11 enters from the light receiving surface.

The solar cell 10 includes a transparent conductive layer 15 and a collector electrode 16 formed on the p-type semiconductor layer 12 (hereinafter, the electrode may be referred to as a “p-side electrode”) and a transparent conductive layer 17 and a collector electrode 18 formed on the n-type semiconductor layer 13 (hereinafter, the electrode may be referred to as an “n-side electrode”). The p-side electrode and the n-side electrode are not in contact with each other and are electrically separated. In other words, the solar cell 10 includes a pair of electrodes formed only on the rear surface side of the n-type crystalline silicon substrate 11. Holes generated on the n-type crystalline silicon substrate 11 and the passivation layer 20 are collected by the p-side electrode, and electrons are collected by the n-side electrode.

The solar cell 10 may have a protective layer (not shown) on the passivation layer 20. The protective layer, for example, inhibits damage to the passivation layer 20 and reduces reflection of light. The protective layer is preferably constituted by a highly light-transmissive material and preferably constituted by silicon oxide (SiO₂), silicon nitride (SiN), silicon oxynitride (SiON) or the like.

The n-type crystalline silicon substrate 11 may be an n-type polycrystalline silicon substrate but is preferably an n-type monocrystal silicon substrate. The n-type crystalline silicon substrate 11 has an n⁺ layer 21 in the vicinity of the interface between the n-type crystalline silicon substrate and the passivation layer 20. The n⁺ layer 21 is doped into an n-type and has a dopant concentration equal to or higher than 1×10¹⁷ cm⁻³. As described later in detail, the average value of the dopant concentration in the n⁺ layer 21 is 1×10¹⁷ cm⁻³ to 1×10²⁰ cm⁻³, and the thickness of the n⁺ layer 21 is equal to or less than 200 nm. The average value of the dopant concentration in the region other than the n⁺ layer 21 of the n-type crystalline silicon substrate 11 is, for example, 1×10¹⁴ cm⁻³ to 5×10¹⁶ cm⁻³. The thickness of the n-type crystalline silicon substrate 11 is, for example, 50 μm to 300 μm.

A textured structure (not shown) is preferably formed on the surface of n-type crystalline silicon substrate 11. The textured structure is a rugged surface structure for reducing surface reflection to thereby increase the amount of light absorbed by the n-type crystalline silicon substrate 11. The textured structure is formed only on the light receiving surface or on both the light receiving surface and the rear surface, for example. The textured structure can be formed by anisotropic-etching the plane (100) of a monocrystal silicon substrate using an alkaline solution, and a pyramid-shaped rugged structure having the plane (111) as a slope is thus formed on the surface of the monocrystal silicon substrate. The height of the rugged structure of the textured structure is 1 μm to 15 μm, for example.

Both the p-type semiconductor layer 12 and the n-type semiconductor layer 13 are layered on the rear surface of the n-type crystalline silicon substrate 11 to respectively form a p-type region and an n-type region on the rear surface. The area of the p-type region is preferably formed larger than the area of the n-type region. The p-type region and the n-type region are, for example, formed in a comb-like pattern in planar view, in which these regions are arranged alternately in one direction and mutually engaged. In the example shown in FIG. 1, a portion of the p-type semiconductor layer 12 is superposed on a portion of the n-type semiconductor layer 13 to form each semiconductor layer (a p-type region and an n-type region) with no gap on the rear surface of the n-type crystalline silicon substrate 11. An insulation layer 14 is provided on a portion where the p-type semiconductor layer 12 and the n-type semiconductor layer 13 overlap each other. The insulation layer 14 is constituted by, for example, silicon oxide, silicon nitride, silicon oxynitride or the like.

The p-type semiconductor layer 12 preferably includes at least a p-type hydrogenated amorphous silicon layer (p-type a-Si:H) and particularly preferably has a laminate structure of an i-type hydrogenated amorphous silicon layer (i-type a-Si:H) and a p-type hydrogenated amorphous silicon layer. One preferable example of the p-type semiconductor layer 12 is formed by laminating an i-type hydrogenated amorphous silicon layer on the rear surface of the n-type crystalline silicon substrate 11 and laminating a p-type hydrogenated amorphous silicon layer on the i-type hydrogenated amorphous silicon layer.

The n-type semiconductor layer 13 preferably includes at least an n-type hydrogenated amorphous silicon layer (n-type a-Si:H) and particularly preferably has a laminate structure of an i-type hydrogenated amorphous silicon layer (i-type a-Si:H) and an n-type hydrogenated amorphous silicon layer. One preferable example of the n-type semiconductor layer 13 is formed by laminating an i-type hydrogenated amorphous silicon layer on the rear surface of the n-type crystalline silicon substrate 11 and laminating an n-type hydrogenated amorphous silicon layer on the i-type hydrogenated amorphous silicon layer.

The i-type a-Si:H layer can be deposited by the chemical vapor deposition (CVD) using a source gas obtained by diluting silane gas (SiH₄) with hydrogen (H₂). A hydrogen-diluted source gas obtained by adding diborane (B₂H₆) to silane is used for deposition of the p-type a-Si:H layer. For deposition of the n-type a-Si:H layer, a source gas containing phosphine (PH₃) instead of diborane is used. The deposition method of each semiconductor layer is not particularly limited.

The transparent conductive layers 15 and 17, each at a position corresponding to the insulation layer 14, are separated from each other. The transparent conductive layers 15 and 17 are constituted by a transparent conductive oxide prepared by doping a metal oxide, for example, indium oxide (In₂O₃), zinc oxide (ZnO) or the like, with tin (Sn), antimony (Sb) or the like. The thickness of the transparent conductive layers 15 and 17 is preferably 30 nm to 500 nm, more preferably 50 nm to 200 nm.

The collector electrodes 16 and 18 are formed respectively on the transparent conductive layers 15 and 17. The collector electrodes 16 and 18 may be formed using a conductive paste but are preferably formed by electroplating. The collector electrodes 16 and 18, which are constituted by, for example, metal such as nickel (Ni), copper (Cu), and silver (Ag), may be a laminate structure of a Ni layer and a Cu layer or may have a tin (Sn) layer as the outermost layer in order to improve their corrosion resistance. The thickness of the collector electrodes 16 and 18 is preferably 0.1 μm to 5 μm, particularly preferably 0.5 μm to 2 μm.

The passivation layer 20 is formed on, for example, approximately the whole area of the light receiving surface of the n-type crystalline silicon substrate 11. The passivation layer 20 has a passivation function and a carrier generating function, as mentioned above. In the present embodiment, the photogenerated carriers (holes and electrons) generated in the passivation layer 20 move to the rear surface side of the n-type crystalline silicon substrate 11, in which the carriers are collected by the p-side electrode and the n-side electrode formed on the rear surface of the passivation layer. The thickness of the passivation layer 20 is preferably 5 nm to 100 nm, particularly preferably 10 nm to 80 nm.

The main component of the passivation layer 20 is preferably amorphous or microcrystalline silicon or silicon carbide. Specifically, the passivation layer 20 is preferably a layer composed of a material selected from (1) to (8) in the following. The passivation layer 20 may include an element that provides the same conductivity type as that of the substrate. The passivation layer 20 preferably has a structure of (1) in the following.
(1) i-type a-Si:H
(2) n-type a-Si:H
(3) i-type hydrogenated amorphous silicon carbide (i-type a-SiC:H)
(4) n-type a-SiC:H
(5) a laminate of i-type or n-type a-Si:H and high-concentration n-type a-Si:H (laminate of i-type or n-type a-Si:H/high-concentration n-type a-Si:H)
(6) a laminate of i-type or n-type a-Si:H/high-concentration n-type hydrogenated microcrystalline silicon (n-type μc-Si:H)
(7) a laminate of i-type or n-type a-SiC:H/high-concentration n-type a-Si:H
(8) a laminate of i-type or n-type a-SiC:H/high-concentration n-type μc-Si:H.

Herein, regarding “a laminate of n-type a-Si:H/high-concentration n-type a-Si:H” as a specific example, “high-concentration” means that the dopant concentration of the latter is higher than that of the former. That is, such a wording means a structure in which two layers each having a different amount of the dopant are layered.

The n⁺ layer 21 is formed in the n-type crystalline silicon substrate 11 by doping the vicinity of the interface between the passivation layer 20 and the n-type crystalline silicon substrate 11 into an n-type. The n⁺ layer 21, which is a region having a dopant concentration equal to or higher than 1×10¹⁷ cm⁻³, is formed in the range of thickness within 200 nm from the interface between the n-type crystalline silicon substrate and the passivation layer 20, that is, the light receiving surface of the n-type crystalline silicon substrate 11. In other words, the n-type crystalline silicon substrate 11 has a region having a dopant concentration equal to or higher than 1×10¹⁷ cm⁻³ only in the range of thickness within 200 nm from the light receiving surface.

The average value of the dopant concentration in the n⁺ layer 21 is 1×10¹⁷ cm⁻³ to 1×10²⁰ cm⁻³. When the average value of the dopant concentration is within the range, a region having a dopant concentration more than 1×10²⁰ cm⁻³ may exist in a portion of the n⁺ layer 21. Preferably the maximum value of the dopant concentration in the n⁺ layer 21 is equal to or less than 1×10²⁰ cm⁻³. The n⁺ layer 21 may have a concentration gradient in which, for example, the dopant concentration decreases as the n⁺ layer 21 becomes farther away from the light receiving surface of the n-type crystalline silicon substrate 11, or may have a dopant concentration approximately homogeneous across the entire layer.

The dopant concentration of the n⁺ layer 21 can be determined by measuring the surface of the n-type crystalline silicon substrate 11 on which a rugged structure is formed by Secondary Ion Mass Spectrometry (SIMS), but can be determined easily by the following method. Specifically, a high-concentration n-type layer, which forms no rugged structure and is formed on a flat surface of a monocrystal silicon substrate, is formed, and the dopant concentration of the high-concentration n-type layer is measured by SIMS. In the case where the n-type crystalline silicon substrate 11 having a rugged structure formed thereon and the flat surface of a monocrystal silicon substrate are doped under the same conditions, it is presumed that the dopant concentration of the n⁺ layer 21 is equivalent to the dopant concentration of the high-concentration n-type layer formed on the flat surface. While the surface of the monocrystal silicon substrate is shaved, the dopant concentration of a plurality of points, each at a different depth from the surface of the crystalline silicon substrate, is measured to obtain the concentration of the dopant at the plurality of points contained in the n⁺ layer 21.

The depth from the surface of the monocrystal silicon substrate when the dopant concentration obtained by the above method is changed to less than 1×10¹⁷ cm⁻³ is taken as the thickness of the n⁺ layer 21. Averaging the dopant concentrations of the plurality of points from the surface of the crystalline silicon substrate to the thickness of the n⁺ layer 21 enables determination of the average value of the dopant concentration in the n⁺ layer 21.

The n⁺ layer 21 is formed using, for example, a thermal diffusion process, a plasma doping processes, or an epitaxial growth process. In the case where the thermal diffusion process or the plasma doping process is employed, a concentration gradient is formed. In the gradient, the dopant concentration becomes highest in the light receiving surface of the n-type crystalline silicon substrate 11, and the concentration is gradually decreased as the distance from the light receiving surface is increased. For example, the n-type crystalline silicon substrate 11 is doped with phosphorus (P) from its light receiving surface such that the dopant concentration within the thickness range of 200 nm from the light receiving surface of the n-type crystalline silicon substrate 11 is to be 1×10¹⁷ cm⁻³ to form the n⁺ layer 21. In the case where the epitaxial growth process is employed, the dopant concentration can be sharply increased at the boundary position of the n⁺ layer 21 and it becomes easy to make the dopant concentration even across the entire n⁺ layer 21, compared with the case in which the thermal diffusion process is used, for example.

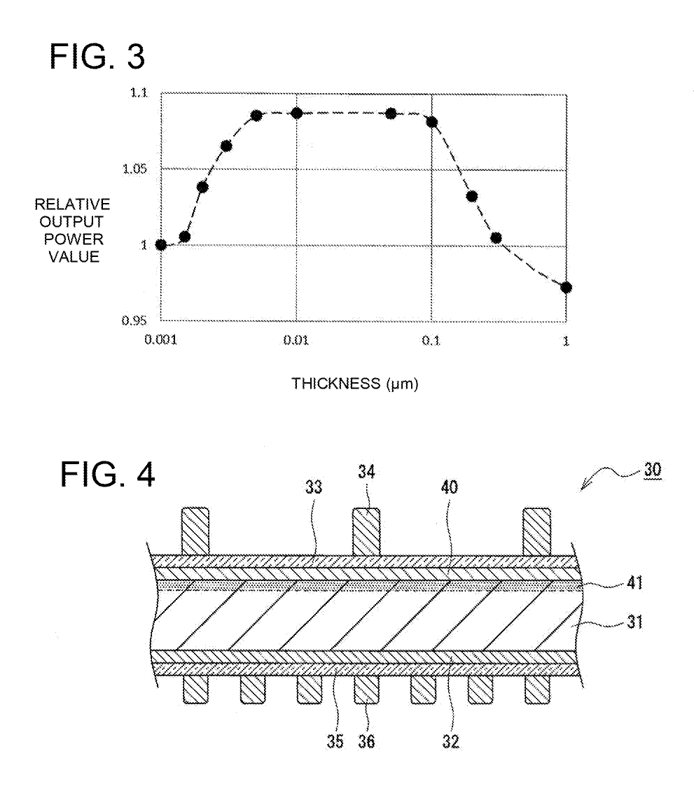

FIG. 2 is a graph showing the relation between the dopant concentration of the n⁺ layer 21 and the relative output power value of the solar cell 10. The relation shown in FIG. 2 is a result of an experiment conducted by assuming that the thickness of the n⁺ layer 21 is 10 nm and that the dopant concentration across the entire n⁺ layer 21 is homogeneous. The relative output power value is a value when the output power of the solar cell having no n⁺ layer 21 is 1 (the same applies to the case of FIG. 3). FIG. 3 is a graph showing the relation between the thickness of the n⁺ layer 21 and the relative output power value of the solar cell 10. The relation shown in FIG. 3 is a result of an experiment conducted by assuming that the dopant concentration of the n⁺ layer 21 is 1×10¹⁹ cm⁻³ (homogeneous across the entire layer).

As shown in FIG. 2, in the case where the dopant concentration of the n⁺ layer 21 (the average value) is 1×10¹⁷ cm⁻³ to 1×10²⁰ cm⁻³, the output power of the solar cell 10 increases greatly. When the average value of dopant concentration in the n⁺ layer 21 is less than 1×10¹⁷ cm⁻³, the recombination due to the interface defects described above cannot be sufficiently inhibited, and the effect caused by the formation of n⁺ layer 21 is unlikely to appear. In contrast, when the average value of the dopant concentration exceeds 1×10²⁰ cm⁻³, for example, the holes generated in the passivation layer 20 easily recombine in the n⁺ layer 21 and reduce the output power. The relation between the dopant concentration of the n⁺ layer 21 and the relative output power value is similar to the relation shown in FIG. 2 in the case of the thickness of the n⁺ layer 21 of about 5 nm to 100 nm. When the thickness exceeds 100 nm, a tendency of the optimal dopant concentration to decrease is observed. The average value of the dopant concentration in the n⁺ layer 21 is preferably 1×10¹⁸ cm⁻³ to 2×10¹⁹ cm⁻³.

As shown in FIG. 3, in the case where the thickness of the n⁺ layer 21 is equal to or less than 200 nm, the output power of the solar cell 10 increases greatly. When the thickness of the n⁺ layer 21 exceeds 200 nm, for example, the holes generated in the passivation layer 20 easily recombine in the n⁺ layer 21 and reduce the output power. The relation between the thickness of the n⁺ layer 21 and the relative output power value is similar to the relation shown in FIG. 3 in the case where the average value of the dopant concentration in the n⁺ layer 21 is about 1×10¹⁸ cm⁻³ to 2×10¹⁹ cm⁻³. When the concentration exceeds 2×10¹⁹ cm⁻³, a tendency of the optimal thickness to decrease is observed. The thickness of the n⁺ layer 21 is preferably 2 nm to 200 nm, particularly preferably 5 nm to 100 nm. When the thickness of the n⁺ layer 21 is less than 2 nm, the recombination due to the interface defects described above cannot be sufficiently inhibited, and the effect caused by the formation of layer 21 may be unlikely to appear.

The n⁺ layer 21 particularly preferably has an average value of the dopant concentration of 1×10¹⁸ cm⁻³ to 2×10¹⁹ cm⁻³ and a thickness of the region in which the dopant concentration is 1×10¹⁸ cm⁻³ to 2×10¹⁹ cm⁻³ in the n⁺ layer 21 of 5 nm to 100 nm. A preferable specific example of the n⁺ layer 21 has an entire thickness of 5 nm to 200 nm or 5 nm to 100 nm and a thickness of the region in which the dopant concentration is 1×10¹⁸ cm⁻³ to 2×10¹⁹ cm⁻³ of 5 nm to 100 nm.

According to the solar cell 10 including the components described above, recombination of the photogenerated carriers in the interface between the n-type crystalline silicon substrate 11 and the passivation layer 20 is inhibited to enable further increase in its output power. That is, the n⁺ layer 21 inhibits the recombination of the photogenerated carriers caused by defects occurring in the interface to reduce the output power loss due to the recombination.

In view of reducing the recombination of the photogenerated carriers in the interface between the n-type crystalline silicon substrate 11 and the passivation layer 20, the passivation layer 20 preferably contains an element that provides the same conductivity type as that of the n-type crystalline silicon substrate 11. Accordingly, electrons are supplied from the passivation layer 20 to the n-type crystalline silicon substrate 11. Then, the electron concentration in the interface increases to enable the recombination rate in the defects to be reduced. The defects in the film in the hydrogenated amorphous silicon layer increase due to doping, and thus, it is to be noted that an excess amount of doping reduces the carrier generating function.

In the case where the passivation layer 20 contains an element that provides the same conductivity type as that of the n-type crystalline silicon substrate 11, the main component of the passivation layer 20 is preferably microcrystalline silicon. This can increase the activation ratio of the dopant in the passivation layer 20. In detail, the n-type hydrogenated microcrystalline silicon has a dopant activation ratio higher than that of the n-type hydrogenated amorphous silicon, and thus, in the case where the amounts of doping are equivalent, the n-type hydrogenated microcrystalline silicon can supply more electrons to the n-type crystalline silicon substrate 11. Accordingly, this can increase the electron concentration of the interface between the n-type crystalline silicon substrate 11 and the passivation layer 20, and reduce the recombination in the defects.

FIG. 4 is a sectional view showing a solar cell 30, which is another example of the embodiment.

As shown in FIG. 4, the solar cell 30 is similar to the solar cell 10 in that it includes an n-type crystalline silicon substrate 31 and a passivation layer 40 formed on the light receiving surface of the substrate, and has a carrier generating function. As in the case of the solar cell 10, the n-type crystalline silicon substrate 31 is preferably an n-type monocrystal silicon substrate, and has an n⁺ layer 41 doped into an n-type in the vicinity of the interface between the n-type crystalline silicon substrate 31 and the passivation layer 40. In contrast, the solar cell 30 is different from the solar cell 10, which includes an electrode formed only on the rear surface, in that it included a light receiving surface electrode formed on the light receiving surface side of n-type crystalline silicon substrate 11 and a rear surface electrode formed on the rear surface side of the n-type crystalline silicon substrate 11.

The light receiving surface electrode and the rear surface electrode respectively include transparent conductive layers 33 and 35 and collector electrodes 34 and 36, each formed on the corresponding transparent conductive layer. The transparent conductive layers 33 and 35 are constituted by transparent conductive oxide, as in the case of the transparent conductive layers 15 and 17 of the solar cell 10. The collector electrodes 34 and 36 are formed by screen printing a conductive paste in a pattern including a large number of finger portions and two or three bus bar portions. The collector electrode 36 is preferably formed to have an area larger than that of the collector electrode 34, and more finger portions are formed in the collector electrode 36 than in the collector electrode 34. Also, the collector electrode 34 is formed thicker than the collector electrode 36. The structure of the electrodes is not particularly limited. For example, a metal layer may be formed on approximately the whole area on the transparent conductive layer 35 as the collector electrode of the rear surface electrode.

The solar cell 30 includes a p-type semiconductor layer 32 formed on the rear surface of the n-type crystalline silicon substrate 31. The p-type semiconductor layer 32 is formed on approximately the whole area of the rear surface of the n-type crystalline silicon substrate 31, for example, and a transparent conductive layer 35 is formed on approximately the whole area of the p-type semiconductor layer 32. In the p-type semiconductor layer 32, materials similar to those of the p-type semiconductor layer 12 of the solar cell 10 can be employed. A passivation layer 40 is formed on the light receiving surface of the n-type crystalline silicon substrate 31. The passivation layer 40 is formed on approximately the whole area of the light receiving surface of the n-type crystalline silicon substrate 31, for example, and a transparent conductive layer 35 is formed on the approximately whole area of the passivation layer 40.

The passivation layer 40 is preferably a layer composed of a material selected from the above (1) to (8) as in the case of the passivation layer 20. In view of reducing the contact resistance with the transparent conductive layer 33 and the like, the passivation layer 40 preferably has a laminate structure selected from the above (5) to (8), and the contact surface to the transparent conductive layer 33 is particularly preferably composed of n-type μc-Si:H.

The n⁺ layer 41, which is a region having a dopant concentration equal to or higher than 1×10¹⁷/cc, in the same manner as the n⁺ layer 21, is formed in the range of thickness within 200 nm from the light receiving surface of the n-type crystalline silicon substrate 31. The average value of the dopant concentration in the n⁺ layer 41 is 1×10¹⁷/cc to 1×10²⁰/cc, preferably 1×10¹⁸/cc to 2×10¹⁹/cc. The thickness of the n⁺ layer 41 is preferably 2 nm to 200 nm, particularly preferably 5 nm to 100 nm. The n⁺ layer 41 particularly preferably has an average value of the dopant concentration of 1×10¹⁸ cm⁻³ to 2×10¹⁹ cm⁻³ and a thickness of the region in which the dopant concentration is 1×10¹⁸ cm⁻³ to 2×10¹⁹ cm⁻³ in the n⁺ layer 41 of 5 nm to 100 nm.

Also in the solar cell 30, as in the case of the solar cell 10, the recombination of photogenerated carriers in the interface between the n-type crystalline silicon substrate 31 and the passivation layer 40 is inhibited to enable further increase in its output power.

In another example of the present embodiment, the n⁺ layer 41 is placed on the light receiving surface the n-type crystalline silicon substrate 31, and the n⁺ layer 41 may be placed on the rear surface of the n-type crystalline silicon substrate 31. In the case where light enters the surface opposite to the surface which light mainly enters to thereby contribute to power generation, the structure in which the n⁺ layer 41 is placed on the rear surface of the n-type crystalline silicon substrate 31 can be employed. In this case, the p-type semiconductor layer 32 is placed on the light receiving surface of the n-type crystalline silicon substrate 31 to form a p-n junction. In another example of the embodiment, formation of the n⁺ layer 41 on the surface of n-type crystalline silicon substrate 31 opposite to the surface on which the p-n junction is formed can increase contribution of the light, entering the surface of the n-type crystalline silicon substrate 31 on which the n⁺ layer 41 is formed, to power generation.

### REFERENCE SIGNS LIST

10, 30 solar cell
11, 31 n-type crystalline silicon substrate
12, 32 p-type semiconductor layer
13 n-type semiconductor layer
14 insulation layer
15, 17, 33, 35 transparent conductive layer
16, 18, 34, 36 collector electrode
20, 40 passivation layer
21, 41 n⁺ layer

1. A solar cell comprising:
a crystalline silicon substrate; and
a passivation layer formed on a light receiving surface of the crystalline silicon substrate, the passivation layer having a carrier generating function;
wherein the crystalline silicon substrate comprises a doped layer in the vicinity of the interface between the crystalline silicon substrate and the passivation layer, and the doped layer is doped to have the same conductivity type as that of the substrate and has a dopant concentration equal to or higher than 1×10¹⁷ cm⁻³, and
an average value of the dopant concentration in the doped layer is 1×10¹⁷ cm⁻³ to 1×10²⁰ cm⁻³, and a thickness of the doped layer is equal to or less than 200 nm.

2. The solar cell according to claim 1, wherein the average value of the dopant concentration in the doped layer is 1×10¹⁸ cm⁻³ to 2×10¹⁹ cm⁻³.

3. The solar cell according to claim 1, wherein the thickness of the doped layer is 5 nm to 100 nm.

4. The solar cell according to claim 1, wherein the average value of the dopant concentration in the doped layer is 1×10¹⁸ cm⁻³ to 2×10¹⁹ cm⁻³ and the thickness of a region in which the dopant concentration is 1×10¹⁸ cm⁻³ to 2×10¹⁹ cm⁻³ is 5 nm to 100 nm.

5. The solar cell according to claim 1, wherein
the crystalline silicon substrate is an n-type crystalline silicon substrate, and
the doped layer is an n⁺ layer formed by doping a surface of the n-type crystalline silicon substrate into an n-type.

6. The solar cell according to claim 1, comprising a pair of electrodes formed on a rear surface side of the crystalline silicon substrate.

7. The solar cell according to claim 1, comprising:
a light receiving surface electrode formed on the light receiving surface side of the crystalline silicon substrate; and
a rear surface electrode formed on the rear surface of the crystalline silicon substrate.

8. The solar cell according to claim 1, wherein a main component of the passivation layer is amorphous or microcrystalline silicon, or silicon carbide.

9. The solar cell according to claim 8, wherein the passivation layer comprises an element that provides the same conductivity type as that of the crystalline silicon substrate.

10. The solar cell according to claim 8, wherein the passivation layer comprises any one of layers of a laminate of i-type a-Si:H, n-type a-Si:H, i-type a-SiC:H, n-type a-SiC:H, i-type or n-type a-Si:H/high-concentration n-type a-Si:H, a laminate of i-type or n-type a-Si:H/high-concentration n-type μc-Si:H, a laminate of i-type or n-type a-SiC:H/high-concentration n-type a-Si:H, or a laminate of i-type or n-type a-SiC:H/high-concentration n-type μc-Si:H.

11. The solar cell according to claim 7, wherein the passivation layer is a layer comprising a laminate of i-type or n-type a-Si:H/high-concentration n-type a-Si:H, a laminate of i-type or n-type a-Si:H/high-concentration n-type μc-Si:H, a laminate of i-type or n-type a-SiC:H/high-concentration n-type a-Si:H, or a laminate of i-type or n-type a-SiC:H/high-concentration n-type μc-Si:H.

12. The solar cell according to claim 11, wherein
the light receiving surface electrode has a transparent conductive layer, and
the contact surface of the passivation layer to the transparent conductive layer comprises the n-type μc-Si:H.
